(19) United States
(12) Patent Application Publication
(10) Pub. No.: US 2016/0005632 A1
(43) Pub. Date: Jan. 7, 2016

(54) SUBSTRATE PROCESSING APPARATUS AND SUBSTRATE PROCESSING METHOD

(71) Applicant: Kabushiki Kaisha Toshiba, Minato-ku (JP)

(72) Inventors: Hisashi NISHIMURA, Yokkaichi (JP); Takeshi SHIBATA, Nonoichi (JP)

(73) Assignee: Kabushiki Kaisha Toshiba, Minato-ku (JP)

(21) Appl. No.: 14/640,743

(22) Filed: Mar. 6, 2015

(30) Foreign Application Priority Data
Jul. 3, 2014 (JP) 2014-138116

(51) Int. Cl. H01L 21/67; H01L 21/66

(52) U.S. Cl. CPC H01L 21/67253; H01L 22/26; H01L 21/67069; H01L 21/67063

(57) ABSTRACT

According to one embodiment, there is provided a substrate processing apparatus including a processing chamber, a substrate processing unit, and a monitoring unit. A stage is placed in the processing chamber. A substrate is able to be put on the stage. The substrate processing unit is configured to process the substrate inside the processing chamber. The monitoring unit is configured to monitor a mass of the substrate via the stage with performing a correction according to a pressure, in a period when the substrate is being processed by the substrate processing unit.

### CROSS-REFERENCE TO RELATED APPLICATIONS

This application is based upon and claims the benefit of priority from Japanese Patent Application No. 2014-138116, filed on Jul. 3, 2014; the entire contents of which are incorporated herein by reference.

### FIELD

Embodiments described herein relate generally to a substrate processing apparatus and substrate processing method.

### BACKGROUND

In the method of manufacturing a semiconductor device, in forming a film on a substrate or processing a film on a substrate, the substrate is processed while monitoring the processing time, and when the processing time reaches a target time corresponding to the predetermined amount of processing, the substrate processing is ended. At this time, the amount of processing for the substrate may greatly deviate from an appropriate processing amount.

### BRIEF DESCRIPTION OF THE DRAWINGS

FIG. 1 is a diagram showing the configuration of a substrate processing apparatus according to a first embodiment;

FIGS. 2A to 2C are diagrams showing the configuration of a stage and substrate support members in the first embodiment;

FIGS. 3A to 3D are graphs showing the operation of the substrate processing apparatus according to the first embodiment;

FIG. 4 is a flow chart showing the operation of the substrate processing apparatus according to the first embodiment;

FIGS. 5A to 5G are diagrams showing processing steps by the substrate processing apparatus according to the first embodiment;

FIG. 6 is a diagram showing the configuration of a substrate processing apparatus according to a second embodiment;

FIGS. 7A to 7D are graphs showing the operation of the substrate processing apparatus according to the second embodiment;

FIG. 8 is a diagram showing the configuration of a substrate processing apparatus according to a third embodiment; and

FIG. 9 is a diagram showing the configuration of a substrate processing apparatus according to a fourth embodiment.

### DETAILED DESCRIPTION

In general, according to one embodiment, there is provided a substrate processing apparatus including a processing chamber, a substrate processing unit, and a monitoring unit. A stage is placed in the processing chamber. A substrate is able to be put on the stage. The substrate processing unit is configured to process the substrate inside the processing chamber. The monitoring unit is configured to monitor a mass of the substrate via the stage with performing a correction according to a pressure, in a period when the substrate is being processed by the substrate processing unit.

Exemplary embodiments of a substrate processing apparatus will be explained below in detail with reference to the accompanying drawings. The present invention is not limited to the following embodiments.

### First Embodiment

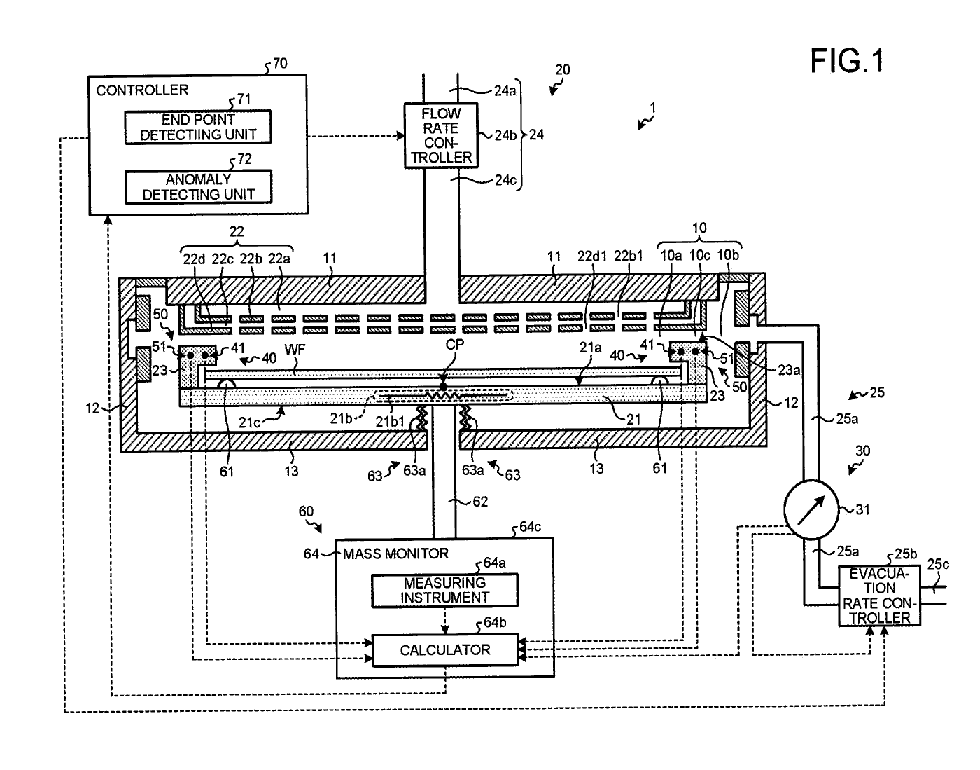

A substrate processing apparatus 1 according to the first embodiment will be described using FIG. 1. FIG. 1 is a diagram showing the configuration of the substrate processing apparatus 1.

The substrate processing apparatus 1 is a film forming apparatus for depositing a predetermined film (e.g., a metal film) on a substrate WF, such as a CVD (Chemical Vapor Deposition) apparatus. The substrate processing apparatus 1 comprises a processing chamber 10, a substrate processing unit 20, a pressure detecting unit 30, a temperature detecting unit 40, a humidity detecting unit 50, a monitoring unit 60, and a controller 70. The substrate processing unit 20 has a stage 21, a shower head 22, a conductance adjustment wall 23, a gas supply unit 24, and a gas evacuation unit 25. The monitoring unit 60 has a plurality of substrate support members 61, a stage 21, a shaft 62, a vacuum sealing structure 63, and a mass monitor 64. The stage 21 is shared by the substrate processing unit 20 and the monitoring unit 60.

The processing chamber 10 is provided as a space enclosed by an upper wall 11, a side wall 12, and a lower wall 13 and which can be evacuated for a vacuum. The stage 21 is placed in the processing chamber 10. A substrate WF can be put on the stage 21 via the plurality of substrate support members 61. The processing chamber 10 includes a film forming chamber 10a, a space 10b, and a communication passage 10c. The film forming chamber 10a is enclosed by the stage 21, the shower head 22, and the conductance adjustment wall 23. Via the communication passage 10c, the film forming chamber 10a and the space 10b communicate.

The stage 21 has a heating unit 21b. The heating unit 21b heats the substrate WF via the stage 21 so that the temperature of the substrate WF becomes a predetermined temperature to deposit a predetermined film during a film forming process. Specifically, the heating unit 21b has a heater 21b1. The heater 21b1 is placed in the stage 21 so as to heat the substrate WF via the stage 21.

The shower head 22 supplies a film forming gas to the surface of the substrate WF. Specifically, the shower head 22 has a gas introduction chamber 22a, a diffusion plate 22b, a diffusion chamber 22c, and a shower plate 22d. The diffusion plate 22b has a plurality of through holes 22b1 via which the gas introduction chamber 22a and the diffusion chamber 22c communicate. The shower plate 22d has a plurality of through holes 22d1 via which the diffusion chamber 22c and the processing chamber 10 communicate.

The shower head 22 supplies the film forming gas supplied from the gas supply unit 24 to the processing chamber 10 while diffusing it. The film forming gas is a gas including material for a film to be deposited over the substrate WF and, for example, if a metal film is to be deposited over the substrate WF, is a gas including the element to be formed into the metal. Or, for example, if a semiconductor film is to be deposited over the substrate WF, the film forming gas is a gas including the element to be formed into the semiconductor. Or, for example, if an insulator film is to be deposited over the substrate WF, the film forming gas is a gas including the element to be formed into the insulator.

The conductance adjustment wall 23 is formed integrally with the stage 21, extending from the outer edge of the stage 21 toward the shower head 22. The conductance adjustment wall 23 may further extend along the shower head 22 inward. The conductance adjustment wall 23 has its upper surface 23a facing the shower plate 22d to form the communication passage 10c and adjusts the flow rate conductance of the film forming gas flowing from the film forming chamber 10a to the space 10b by the width along a vertical direction of the communication passage 10c. A drive unit (not shown) drives the stage 21 and the conductance adjustment wall 23 in such a direction as to come closer to the shower head 22 so that the width along a vertical direction of the communication passage 10c becomes a target width determined through experiment beforehand, in the film forming process.

The gas supply unit 24 supplies the film forming gas to the shower head 22. The gas supply unit 24 has a supply conduit 24a, a flow rate controller 24b, and a supply conduit 24c. The film forming gas is supplied from a gas supply source (not shown) into the supply conduit 24a. The flow rate controller 24b controls the flow rate of the film forming gas flowing from the supply conduit 24a to the supply conduit 24c under control by the controller 70.

The gas evacuation unit 25 evacuates the film forming gas from the space 10b of the processing chamber 10. The gas evacuation unit 25 has an evacuation conduit 25a, an evacuation rate controller 25b, and an evacuation conduit 25c. The film forming gas flows out of the space 10b into the evacuation conduit 25a. The evacuation rate controller 25b controls the evacuation rate of the film forming gas flowing from the evacuation conduit 25a to the evacuation conduit 25c based on the detecting result of the pressure detecting unit 30 under control by the controller 70. The evacuation rate controller 25b can control the evacuation rate so that the pressure in the processing chamber 10 becomes, e.g., several tens to 10⁻¹ Torr. The film forming gas flowing out into the evacuation conduit 25c is evacuated into an evacuation unit (not shown).

The pressure detecting unit 30 detects the pressure in the processing chamber 10. The pressure detecting unit 30 has a pressure sensor 31. The pressure sensor 31 is provided, for example, in the evacuation conduit 25a and can detect the pressure of the film forming gas passing through the evacuation conduit 25a as the pressure in the processing chamber 10. The pressure sensor 31 may be provided in another place (e.g., near the space 10b) as long as it can detect the pressure in the processing chamber 10. The pressure detecting unit 30 supplies the detecting result to the mass monitor 64.

The temperature detecting unit 40 detects the temperature of the film forming gas (processing gas). The temperature detecting unit 40 has a temperature sensor 41. The temperature sensor 41 is provided, for example, in the conductance adjustment wall 23 and can detect the temperature of the film forming gas passing through the communication passage 10c. The temperature sensor 41 may be provided in another place as long as it can detect the temperature of the film forming gas. The temperature detecting unit 40 supplies the detecting result to the mass monitor 64.

The humidity detecting unit 50 detects the humidity in the processing chamber 10. The humidity detecting unit 50 has a humidity sensor 51. The humidity sensor 51 is provided, for example, in the conductance adjustment wall 23 and can detect the humidity in the communication passage 10c as the humidity in the processing chamber 10. The humidity sensor 51 may be provided in another place as long as it can detect the humidity in the processing chamber 10. The humidity detecting unit 50 supplies the detecting result to the mass monitor 64.

The monitoring unit 60 monitors the mass of the substrate WF in situ during the film forming process. That is, the monitoring unit 60 monitors the mass of the substrate WF via the stage 21, using the amount of correction agreeing with the pressure detected by the pressure detecting unit 30, the temperature detected by the temperature detecting unit 40, and the humidity detected by the humidity detecting unit 50. Thus, the monitoring unit 60 can monitor the mass of the substrate WF in real time during the film forming process in cooperation with the pressure detecting unit 30, temperature detecting unit 40, and humidity detecting unit 50.

Specifically, the plurality of substrate support members 61 protrude from the surface 21a of the stage 21 so as to receive force corresponding to gravity acting on the substrate WF when the substrate WF is put on the stage 21. Each substrate support member 61 is structured to support the back side of the substrate WF in point contact and is formed in, e.g., a substantially hemisphere shape. Thus, the total value of magnitudes of forces respectively received by the substrate support members 61 can be regarded as corresponding to gravity acting on the substrate WF.

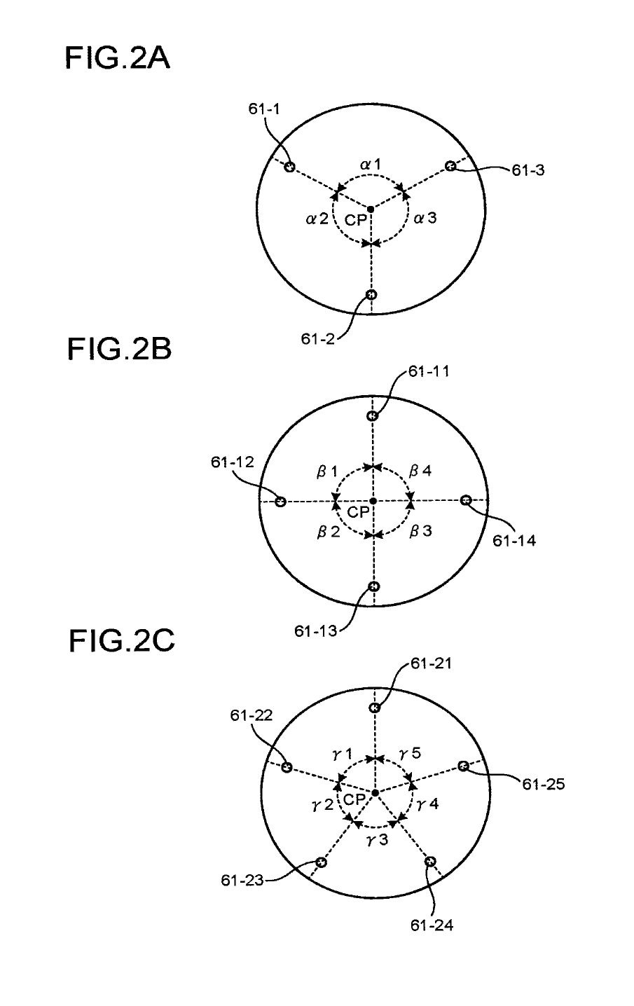

Letting N be an integer of three or greater, the number of substrate support members 61 can be N. In this case, as shown in FIGS. 2A to 2C, N number of substrate support members 61 are provided in positions N-fold symmetrical with respect to the center CP of the surface 21a of the stage 21 when seen in a direction perpendicular to the surface 21a of the stage 21. FIGS. 2A to 2C are diagrams showing the configuration of the stage 21 and the substrate support members 61 when seen in a direction perpendicular to the surface 21a of the stage 21. Hence, the magnitudes of respective forces that N number of substrate support members 61 receive from the substrate WF can be made equivalent, so that the N number of substrate support members 61 can stably support the substrate WF.

For example, in the case of FIG. 2A, N=3, and three substrate support members 61-1 to 61-3 are provided in positions threefold symmetrical. That is, angles α1 to α3 made by straight lines joining the substrate support members 61-1 to 61-3 to the center CP are equivalent and each substantially 120 degrees.

For example, in the case of FIG. 2B, N=4, and four substrate support members 61-11 to 61-14 are provided in positions fourfold symmetrical. That is, angles β1 to β4 made by straight lines joining the substrate support members 61-11 to 61-14 to the center CP are equivalent and each substantially 90 degrees.

For example, in the case of FIG. 2C, N=5, and five substrate support members 61-21 to 61-25 are provided in positions fivefold symmetrical. That is, angles γ1 to γ5 made by straight lines joining the substrate support members 61-21 to 61-25 to the center CP are equivalent and each substantially 72 degrees.

The shaft 62 shown in FIG. 1 is provided to be able to move up and down following the up-and-down movement of the stage 21 between the stage 21 and the mass monitor 64. Thus, the shaft 62 transmits force received by the stage 21 from the substrate support members 61 to the mass monitor 64.

The vacuum sealing structure 63 vacuum-seals the gap between the back side 21c of the stage 21 and the lower wall 13 so as to maintain a vacuum in the processing chamber 10 while the shaft 62 moves up and down. Specifically, the vacuum sealing structure 63 has a bellows structure 63a. The upper end of the bellows structure 63a vacuum-seals against the back side 21c of the stage 21 via seal material, a seal tape, and/or the like. The lower end of the bellows structure 63a vacuum-seals against the lower wall 13 via seal material, a seal tape, and/or the like. The bellows structure 63a is structured to be able to stretch and contract vertically and formed of, e.g., resin. Since the bellows structure 63a is structured to be able to stretch and contract vertically, force-transmission loss can be easily reduced when the shaft 62 transmits force received by the stage 21 to the mass monitor 64 by the up-and-down movement.

The mass monitor 64 monitors the mass of the substrate WF according to the magnitude of force transmitted via the shaft 62, the pressure detected by the pressure detecting unit 30, the temperature detected by the temperature detecting unit 40, and the humidity detected by the humidity detecting unit 50. The mass monitor 64 has a measuring instrument 64a and a calculator 64b. The measuring instrument 64a and calculator 64b are housed in the housing 64c of the mass monitor 64. The measuring instrument 64a and calculator 64b are connected in the housing 64c by lines which allow high speed communication. Each of the measuring instrument 64a and calculator 64b is connected to the lines via, e.g., a high speed communication interface.

The measuring instrument 64a measures the magnitude of force transmitted via the shaft 62 as the mass of the substrate WF acting on the substrate support members 61. A publicly-known electronic balance can be used as the measuring instrument 64a. Letting σ be variance, e.g., when a film of material made mainly of Ta is formed 1 Å thick, the measurement accuracy of the measuring instrument 64a can be set such that 1σ<0.08 mg. The measuring instrument 64a supplies the measuring result to the calculator 64b.

The calculator 64b corrects the measuring result of the measuring instrument 64a according to the pressure detected by the pressure detecting unit 30, the temperature detected by the temperature detecting unit 40, and the humidity detected by the humidity detecting unit 50.

Although the mass of the substrate WF increases according to the thickness of the film formed after the film forming process starts, the mass of the substrate WF acting on the substrate support members 61 is affected by buoyancy due to the film forming gas existing around the substrate WF. This buoyancy varies depending mainly on the pressure in the processing chamber 10 and can further vary depending on the temperature of the film forming gas and the humidity in the processing chamber 10 as well. That is, letting M be the mass of the substrate WF to be monitored, the following equation 1 holds.

M=W+ΔW(T,H,P) Eq. 1

In the equation 1, W denotes the measuring result of the measuring instrument 64a, that is, the mass of the substrate WF agreeing with force acting on the substrate support members 61. ΔW denotes buoyancy that the substrate WF receives from the film forming gas existing around the substrate WF. T denotes the detecting result of the temperature detecting unit 40, that is, the temperature of the film forming gas. H denotes the detecting result of the humidity detecting unit 50, that is, the humidity in the processing chamber 10. P denotes the detecting result of the pressure detecting unit 30, that is, the pressure in the processing chamber 10.

That is, the calculator 64b obtains the correction amount ΔW agreeing with the pressure detected by the pressure detecting unit 30, the temperature detected by the temperature detecting unit 40, and the humidity detected by the humidity detecting unit 50. The calculator 64b corrects the measuring result W of the measuring instrument 64a by the correction amount ΔW according to the above equation 1 to obtain a monitored value M of the mass of the substrate WF.

It should be noted that, letting ρ_{A} be the density of air, ρ_{W} be the density of the substrate WF, and Δρ be the density of calibration mass to be used to calibrate the measuring instrument 64a, the correction amount ΔW is expressed by the following equation 2.

ΔW=W×(ρ_{A}/ρ_{W}−ρ_{A}/Δβ)/(1−ρ_{A}/ρ_{W}) Eq. 2

The density of air ρ_{A} is expressed by, e.g., the following equation 3, using the detecting result T of the temperature detecting unit 40, the detecting result H of the humidity detecting unit 50, and the detecting result P of the pressure detecting unit 30.

ρ_{A}={0.03485P−0.00132×(0.0398T²−0.1036T+9.5366)×H}÷{(273.14+T)×1000} Eq. 3

From the equations 2 and 3, it is seen that the correction amount ΔW is a function of the detecting result T of the temperature detecting unit 40, the detecting result H of the humidity detecting unit 50, and the detecting result P of the pressure detecting unit 30.

The calculator 64b can receive the measuring result from the measuring instrument 64a in real time and receive the detecting results of the pressure detecting unit 30, of the temperature detecting unit 40, and of the humidity detecting unit 50 in real time during the film forming process. Then the calculator 64b can execute a correction process according to the aforementioned equation 1 using the measuring result from the measuring instrument 64a and the detecting results of the pressure detecting unit 30, of the temperature detecting unit 40, and of the humidity detecting unit 50 and supply the obtained monitored value M to the controller 70 in real time. That is, the mass monitor 64 can monitor the mass of the substrate WF while correcting the mass in real time during the film forming process for the substrate WF and supply the monitoring result to the controller 70.

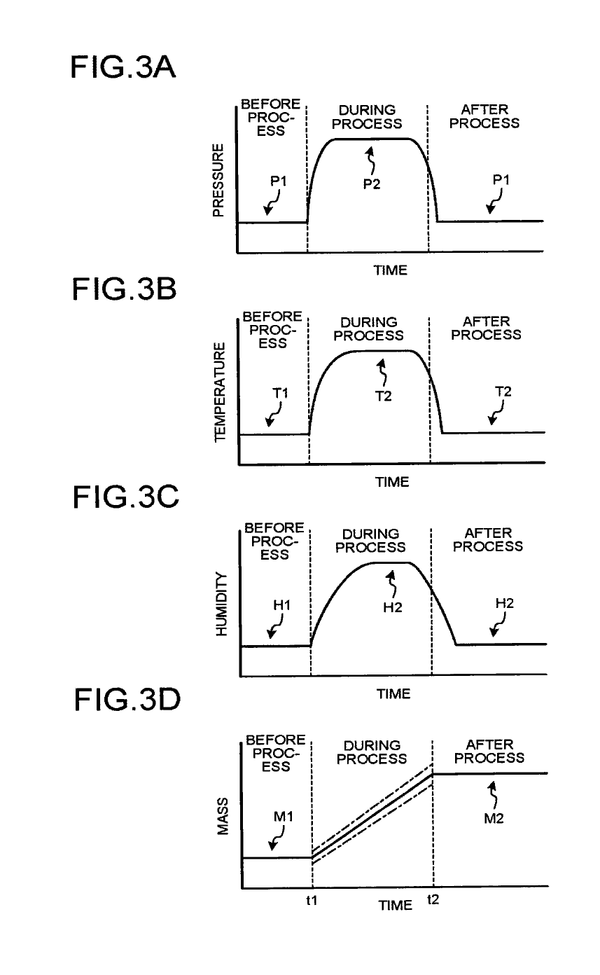

For example, the detecting results of the pressure detecting unit 30, of the temperature detecting unit 40, and of the humidity detecting unit 50 demonstrate characteristics shown in FIGS. 3A to 3C. That is, after the film forming process starts, it takes time for the pressure in the processing chamber 10, the temperature of the processing gas, and the humidity in the processing chamber 10 to change respectively from initial values P1, T1, H1 to target values P2, T2, H2 and become stable. Even in this case, the mass monitor 64 can start monitoring the mass of the substrate WF accurately quickly after the film forming process for the substrate WF starts, as shown in FIG. 3D. For example, the mass monitor 64 can monitor the mass of the substrate WF gradually increasing from an initial value M1 after timing t1. FIGS. 3A to 3D are graphs showing the operation of the substrate processing apparatus 1.

The controller 70 shown in FIG. 1 controls the operation of the substrate processing unit 20. Further, the controller 70 can perform control based on the monitoring result of the monitoring unit 60. Specifically, the controller 70 has an end point detecting unit 71 and an anomaly detecting unit 72.

The end point detecting unit 71 has the substrate processing unit 20 finish processing the substrate WF based on the monitoring result of the monitoring unit 60. For example, during the film forming process, at timing t2 when the mass being monitored by the monitoring unit 60 reaches a target value M2 as shown in FIG. 3D, the end point detecting unit 71 determines that the amount of film formation over the substrate WF has reached a target amount of film formation and has the substrate processing unit 20 finish processing the substrate WF.

The anomaly detecting unit 72 detects an anomaly in the substrate processing unit 20 based on the monitoring result of the monitoring unit 60. When detecting an anomaly in the substrate processing unit 20, the anomaly detecting unit 72 has the substrate processing unit 20 suspend processing the substrate WF. For example, the anomaly detecting unit 72 obtains the temporal rate of change (rate of increase) in the monitored value M of the monitoring unit 60 in real time during the film forming process. If the temporal rate of change (rate of increase) in the monitored value M of the monitoring unit 60 is out of a threshold range, the anomaly detecting unit 72 determines that an anomaly has occurred in the substrate processing unit 20 and has the substrate processing unit 20 suspend processing the substrate WF. Or, for example, if the monitored value M of the monitoring unit 60 is out of a threshold range as indicated by dot-dashed lines in FIG. 3D during the film forming process, the anomaly detecting unit 72 determines that an anomaly has occurred in the substrate processing unit 20 and has the substrate processing unit 20 suspend processing the substrate WF.

It should be noted that, the threshold range used in detecting anomalies may be theoretically estimated from the partial pressures of the film forming gas, the vacuum degree (pressure) in the processing chamber 10, the temperature of the film forming gas, and the volume of the substrate WF. Or the flow-rate control value and evacuation-rate control value of the film forming gas, the detected pressure, temperature, and humidity, and the correlation between the measured mass and the actual amount of film formation may be acquired beforehand through experiment to set the threshold range used in detecting anomalies at empirical values determined from them.

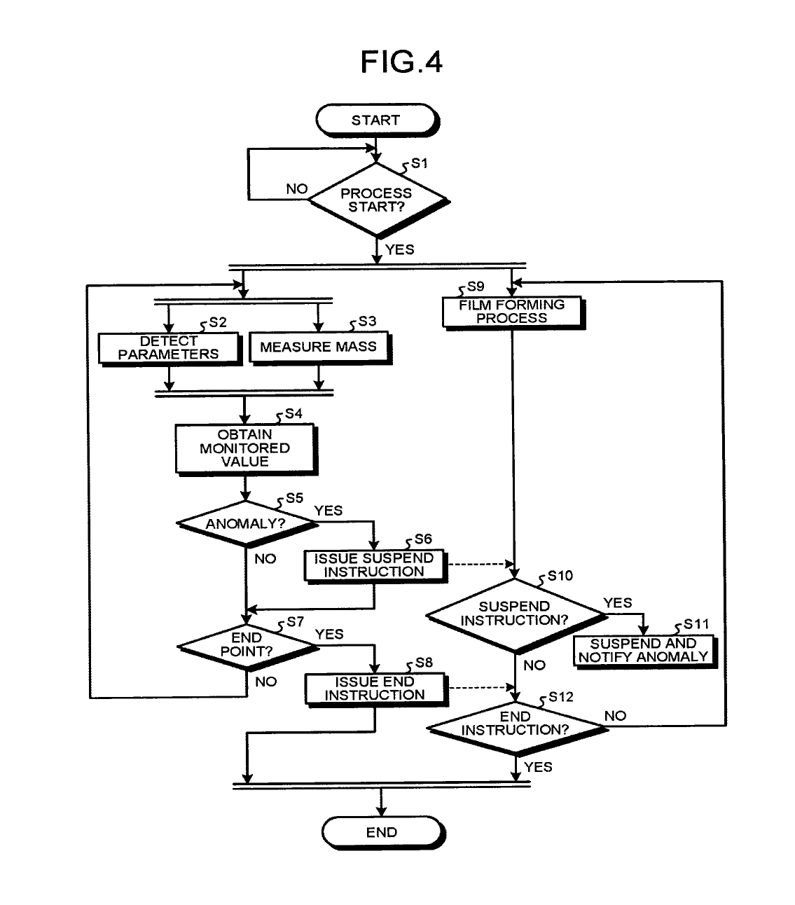

Next, the operation of the substrate processing apparatus 1 will be described using FIG. 4. FIG. 4 is a flow chart showing the operation of the substrate processing apparatus 1.

The controller 70 waits until receiving an instruction to start the film forming process (No at S1) and, when receiving an instruction to start the film forming process (Yes at S1), makes the process of S2 to S8 and the process of S9 to S12 be performed in parallel.

That is, the pressure detecting unit 30, the temperature detecting unit 40, and the humidity detecting unit 50 detect process parameters (pressure, temperature, humidity) respectively (S2). The monitoring unit 60 measures the mass of the substrate WF (S3). In parallel with this, the substrate processing unit 20 starts the film forming process on the substrate WF (S9). The monitoring unit 60 monitors the mass of the substrate WF via the stage 21 using the correction amount agreeing with the pressure detected by the pressure detecting unit 30, the temperature detected by the temperature detecting unit 40, and the humidity detected by the humidity detecting unit 50. That is, the monitoring unit 60 obtains the correction amount agreeing with the pressure detected by the pressure detecting unit 30, the temperature detected by the temperature detecting unit 40, and the humidity detected by the humidity detecting unit 50 and corrects the result of measuring the mass of the substrate WF by the obtained correction amount to obtain the monitored value of the mass of the substrate WF (S4). The monitoring unit 60 supplies the obtained monitored value to the controller 70.

The controller 70 determines whether an anomaly has occurred in the substrate processing unit 20 based on the monitoring result of the monitoring unit 60 (S5). For example, the controller 70 obtains the temporal rate of change in the monitored value M of the monitoring unit 60 in real time and determines whether the temporal rate of change in the monitored value M of the monitoring unit 60 is out of the threshold range. Or, for example, the controller 70 determines whether the monitored value M of the monitoring unit 60 is out of the threshold range as indicated by dot-dashed lines in FIG. 3D. If the value according to the monitoring result is out of the threshold range, the controller 70 determines that an anomaly has occurred in the substrate processing unit 20 (Yes at S5) and issues a suspend instruction to suspend the processing to the substrate processing unit 20 (S6). Accordingly, the substrate processing unit 20 receives the suspend instruction (Yes at S10) and hence suspends the film forming process for the substrate WF and simultaneously notify an anomaly in the substrate processing unit 20 by a predetermined notifying means (S11). As the predetermined notifying means, a visual method such as lighting a lamp (not shown) or displaying an error message on the screen of a display device (not shown), or an auditory method such as sounding a buzzer (not shown) or outputting an error message in voice through a speaker (not shown) may be used.

If an anomaly has not occurred in the substrate processing unit 20 (No at S5); the controller 70 makes the process proceed to S7. For example, FIG. 3D illustrates the case where the monitored value M indicated by a solid line in FIG. 3D is within the threshold range indicated by dot-dashed lines, that is, an anomaly has not occurred. Accordingly, the substrate processing unit 20 does not receive a suspend instruction (No at S10), and hence the process proceeds to S12.

The controller 70 determines whether it has reached the end point of the film forming process based on the monitoring result of the monitoring unit 60 (S7). For example, when the mass being monitored by the monitoring unit 60 reaches the target value M2 during the film forming process, the controller 70 determines that it has reached the end point of the film forming process (Yes at S7) and issues an end instruction to end the processing to the substrate processing unit 20 (S8). Accordingly, the substrate processing unit 20 receives the end instruction (Yes at S12), and hence ends the film forming process for the substrate WF.

When it has not reached the end point of the film forming process (No at S7), the controller 70 makes the process return to S2, S3. Accordingly, the substrate processing unit 20 does not receive an end instruction (No at S12), and hence the process returns to S9.

Here, consider the case where the substrate processing apparatus 1 detects the end point of the processing of the substrate WF from the processing time of the substrate WF. In this case, if the pressure in the processing chamber 10 is higher, that is, if the amount of the film forming gas in the processing chamber 10 is greater, the rate of film formation is higher. Hence, if the detection of the end point of the film forming process is performed by means of time management, then the thickness of the formed film (amount of processing) may greatly exceed a target thickness (target amount of processing).

Alternatively, consider the case where the substrate processing apparatus 1 monitors the mass of the substrate WF without correcting the mass. In this case, if the pressure in the processing chamber 10 is higher, that is, if the amount of the film forming gas in the processing chamber 10 is greater, the mass of the substrate WF tends to be measured lower than its-actual mass because of the influence of buoyancy that the substrate WF receives from the film forming gas. Hence, if the end point of the film forming process is detected from the mass of the substrate WF not corrected, then the thickness of the formed film (amount of processing) may greatly exceed a target thickness (target amount of processing).

In contrast, in the first embodiment, the monitoring unit 60 in the substrate processing apparatus 1 monitors the mass of the substrate WF via the stage 21 using the correction amount agreeing with the pressure detected by the pressure detecting unit 30, the temperature detected by the temperature detecting unit 40, and the humidity detected by the humidity detecting unit 50 during the time that the substrate processing unit 20 is processing the substrate WF. Thus, the mass of the substrate WF can be monitored highly accurately with being corrected in real time in parallel with the processing of the substrate WF by the substrate processing unit 20. As a result, when the mass of the substrate WF reaches a target value, that is, at the time point that it can be determined that the amount of processing for the substrate WF has reached a target processing amount, the end point detecting unit 71 can end the processing of the substrate WF, and thus variation in the amount of processing in the film forming process can be reduced. That is, the substrate WF can be easily processed with an appropriate processing amount (a processing amount within a permissible range with respect to the target processing amount).

Further, in the first embodiment, because the substrate WF can be easily processed with an appropriate processing amount (a processing amount within a permissible range with respect to the target processing amount), the total processing time when a plurality of films are consecutively formed can be reduced.

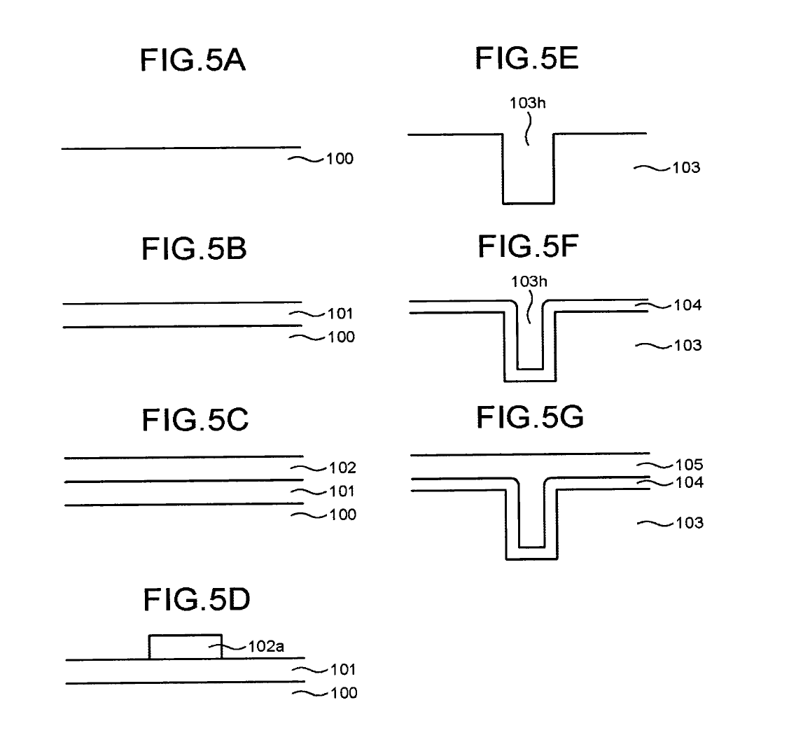

For example, in the step shown in FIG. 5A, an insulating film 100 is formed on the substrate WF; in the step shown in FIG. 5B, a polysilicon film 101 is formed on the insulating film 100; in the step shown in FIG. 5C, a tungsten film 102 is formed on the polysilicon film 101; and in the step shown in FIG. 5D, the tungsten film is processed by etching into the tungsten film 102a. Because the substrate WF can be easily processed with an appropriate processing amount (a processing amount within a permissible range with respect to the target processing amount) in each of the steps shown in FIGS. 5A to 5C, a QC (Quality Control) step for inspecting whether the film is formed with an appropriate thickness, need not be provided to come after the step. Hence, the steps shown in FIGS. 5A to 5C can be executed consecutively, and thus the total processing time of the steps of FIGS. 5A to 5C can be reduced. For example, if the steps shown in FIGS. 5A to 5C can be executed in the same processing chamber, not only the time for QC steps can be reduced, but also the time for transfer can be reduced.

Or, for example, in the step shown in FIG. 5E, holes 103h are formed in an insulating film 103; in the step shown in FIG. 5F, a barrier metal film 104 of, e.g., Ti, TiN, or Ta is formed on the bottoms and side surfaces of the holes 103h; and in the step shown in FIG. 5G, a Cu film 105 is formed filling the holes 103h. Because the substrate WF can be easily processed with an appropriate processing amount (a processing amount within a permissible range with respect to the target processing amount) in each of the steps shown in FIGS. 5F and 5G, a QC (Quality Control) step for inspecting whether the film is formed with an appropriate thickness need not be provided to come after the step. Hence, the steps shown in FIGS. 5F and 5G can be executed consecutively, and thus the total processing time of the steps of FIGS. 5F and 5G can be reduced. For example, if the steps shown in FIGS. 5F and 5G can be executed in the same processing chamber, not only the time for QC steps can be reduced, but also the time for transfer can be reduced.

Here, consider the case where the substrate processing apparatus 1 monitors the thickness of a formed film by an optical method such as an ellipsometry method. In this case, it is difficult to measure the thickness of a film of metal, polysilicon, or the like that is likely to reflect light, and thus it is difficult to detect the end point of the film forming process.

In contrast, in the first embodiment, the monitoring unit 60 can highly accurately monitor the mass of the substrate WF with correcting in real time in parallel with the processing of the substrate WF by the substrate processing unit 20. Thus, even for a film of metal, polysilicon, or the like that is likely to reflect light, the detection of the end point of the film forming process can be highly accurately performed.

Further, in the first embodiment, in the substrate processing apparatus 1, the anomaly detecting unit 72 detects an anomaly in the substrate processing unit 20 in real time based on the monitoring result of the monitoring unit 60 in parallel with the processing of the substrate WF by the substrate processing unit 20. Thus, an anomaly in the substrate processing unit 20 can be quickly detected, so that the processing of the substrate WF can be suspended before going into a failed state. As a result, the frequency of reworking substrates WF can be reduced, and thus the production cost of a semiconductor device using the substrate WF can be reduced.

It should be noted that, although the first embodiment illustrates the case where the substrate processing apparatus 1 is a thermal CVD apparatus, the substrate processing apparatus 1 may be a CVD apparatus which executes the film forming process by an APCVD (Atmospheric Pressure CVD) method, or a CVD apparatus which executes the film forming process by an SACVD (Semi-Atmospheric pressure CVD) method, or a CVD apparatus which executes the film forming process by an LPCVD (Low Pressure CVD) method, or a CVD apparatus which executes the film forming process by a pressurized CVD method, or a CVD apparatus which executes the film forming process by a plasma CVD method. Or the substrate processing apparatus 1 may be a PVD (Physical Vapor Deposition) apparatus such as a sputtering apparatus.

Or the calculator 64b of the monitoring unit 60 can be housed in the housing of the controller 70 instead of being housed in the housing 64c of the mass monitor 64.

Or the monitoring unit 60 monitors the mass of the substrate WF via the stage 21, with using a predetermined pressure P′ (e.g., a target pressure of the present processing step), instead of using the pressure P detected by the pressure detecting unit 30. The predetermined pressure P′ can be constant. In this case, for example, the calculator 64b can correct the measuring result W of the measuring instrument 64a by the correction amount ΔW according to the above equation 1 where the predetermined pressure P′ instead of the pressure P is plugged in to obtain the monitor value of the mass of the substrate WF.

Or the monitoring unit 60 may obtain the amount of correction without taking humidity into account. The monitoring unit 60 may monitor the mass of the substrate WF via the stage 21 using a correction amount agreeing with the pressure detected by the pressure detecting unit 30 and the temperature detected by the temperature detecting unit 40. For example, if the dependence on humidity of buoyancy that the substrate WF receives in the film forming process is smaller than its dependence on pressure and temperature, then the following approximate equation 4 holds.

M≈W+ΔW(T,P) Eq. 4

That is, the calculator 64b of the mass monitor 64 obtains the correction amount ΔW agreeing with the pressure detected by the pressure detecting unit 30 and the temperature detected by the temperature detecting unit 40. The calculator 64b corrects the measuring result W of the measuring instrument 64a by the correction amount ΔW according to the above approximate equation 4 to obtain the monitored value M of the mass of the substrate WF.

As such, in the monitoring unit 60, the calculator 64b obtains the amount of correction without taking humidity into account, and hence the amount of computation of the calculator 64b can be reduced, so that the arithmetic processing time can be reduced.

Or the monitoring unit 60 may obtain the amount of correction without taking temperature and humidity into account. The monitoring unit 60 may monitor the mass of the substrate WF via the stage 21 using a correction amount agreeing with the pressure detected by the pressure detecting unit 30. For example, if the dependence on temperature and humidity of buoyancy that the substrate WF receives in the film forming process is smaller than its dependence on pressure, then the following approximate equation 5 holds.

M≈W+ΔW(P) Eq. 5

That is, the calculator 64b of the mass monitor 64 obtains the correction amount ΔW agreeing with the pressure detected by the pressure detecting unit 30. The calculator 64b corrects the measuring result W of the measuring instrument 64a by the correction amount ΔW according to the above approximate equation 5 to obtain the monitored value M of the mass of the substrate WF.

As such, in the monitoring unit 60, the calculator 64b obtains the amount of correction without taking temperature and humidity into account, and hence the amount of computation of the calculator 64b can be further reduced, so that the arithmetic processing time can be further reduced.

### Second Embodiment

Next, a substrate processing apparatus 200 according to the second embodiment will be described. Description will be made below focusing on the differences from the first embodiment.

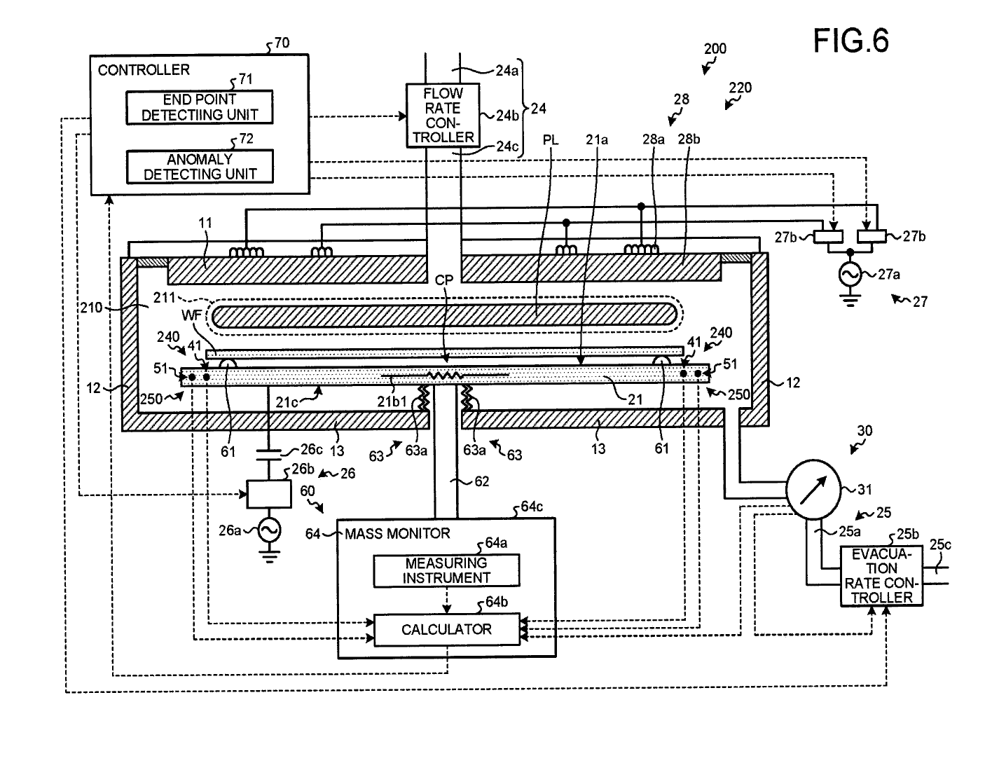

The substrate processing apparatus 200 is an etching apparatus for processing a predetermined film over a substrate WF, such as an RIE (Reactive Ion Etching) apparatus. The substrate processing apparatus 200 comprises a processing chamber 210, a substrate processing unit 220, a temperature detecting unit 240, and a humidity detecting unit 250 instead of the processing chamber 10, substrate processing unit 20, temperature detecting unit 40, and humidity detecting unit 50 (see FIG. 1). FIG. 6 is a diagram showing the configuration of the substrate processing apparatus 200. The substrate processing unit 220 does not have the shower head 22 nor the conductance adjustment wall 23 (see FIG. 1), but further has a power supply 26, a power supply 27, and a plasma generating unit 28. A temperature sensor 41 of the temperature detecting unit 240 may be provided in the stage 21. A humidity sensor 51 of the humidity detecting unit 250 may be provided in the stage 21.

The power supply 27 is one which supplies power for processing the substrate WF and supplies high-frequency power to the plasma generating unit 28. The power supply 27 has a high-frequency power supply 27a and a matching box 27b.

The plasma generating unit 28 generates plasma PL in a space 211 away from the stage 21 inside the processing chamber 210 using power supplied from the power supply 27. Specifically, the plasma generating unit 28 has an antenna coil 28a and a dielectric wall 28b. The high-frequency power supply (RF power supply) 27a generates high-frequency power to supply to the antenna coil 28a. Once impedance matching is established between the high-frequency power supply 27a and the antenna coil 28a by the matching box 27b under control by the controller 70, electromagnetic waves pass through the dielectric wall 28b to be introduced into the space 211 inside the processing chamber 210. Plasma PL is generated by ionization of a processing gas in the space 211 inside the processing chamber 210, and ions (such as F⁺ and CF₃⁺), together with radicals, are generated from the processing gas.

The power supply 26 generates a bias voltage for the stage 21 placed on the bottom side in the processing chamber 210. Specifically, the power supply 26 has a high-frequency power supply (RF power supply) 26a, a matching box 26b, and a blocking capacitor 26c. The high-frequency power supply 26a generates high-frequency power, and once impedance matching is established by the matching box 26b under control by the controller 70, the bias voltage is applied to the stage 21 via the blocking capacitor 26c. When the bias voltage is applied, a potential difference occurs between the Plasma PL and the stage 21, and thus ions (such as F⁺ and CF₃⁺) generated in the plasma PL region are attracted to the substrate WF, so that anisotropic etching is performed.

At this time, the mass monitor 64 monitors the mass of the substrate WF according to the magnitude of force transmitted via the shaft 62, the pressure detected by the pressure detecting unit 30, the temperature detected by the temperature detecting unit 240, and the humidity detected by the humidity detecting unit 250.

Specifically, the measuring instrument 64a measures the magnitude of force transmitted via the shaft 62 as the mass of the substrate WF agreeing with force acting on the substrate support members 61 during the etching process. The measuring instrument 64a supplies the measuring result to the calculator 64b.

The calculator 64b can receive the measuring result from the measuring instrument 64a in real time and receive the detecting results of the pressure detecting unit 30, of the temperature detecting unit 240, and of the humidity detecting unit 250 in real time during the etching process. Then the calculator 64b can execute a correction process according to the aforementioned equation 1 using the measuring result from the measuring instrument 64a and the detecting results of the pressure detecting unit 30, of the temperature detecting unit 240, and of the humidity detecting unit 250 and supply the obtained monitored value M to the controller 70 in real time. That is, the mass monitor 64 can monitor the mass of the substrate WF while correcting the mass in real time during the etching process for the substrate WF and supply the monitoring result to the controller 70.

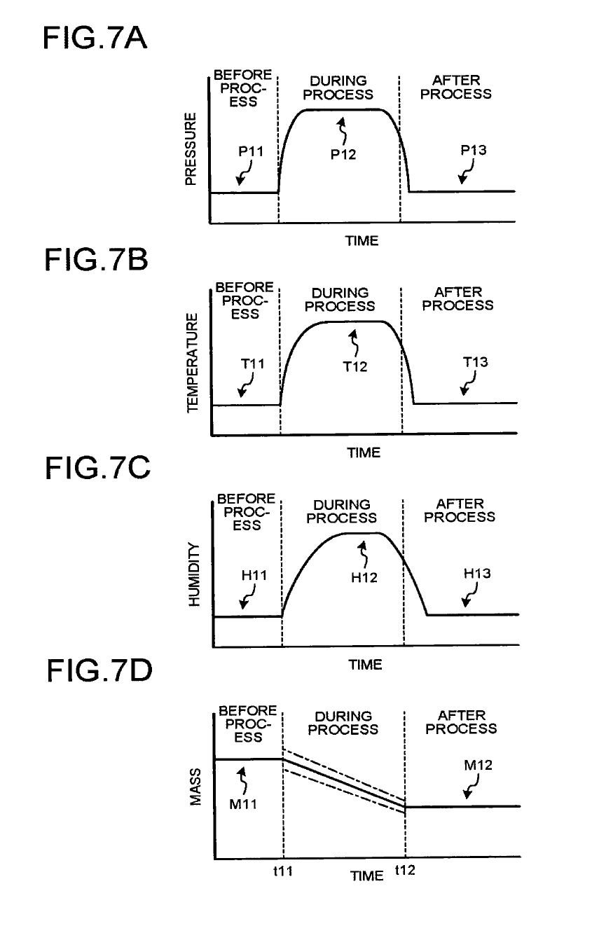

For example, the detecting results of the pressure detecting unit 30, of the temperature detecting unit 240, and of the humidity detecting unit 250 demonstrate characteristics shown in FIGS. 7A to 7C. That is, after the etching process starts, it takes time for the pressure in the processing chamber 210, the temperature of the processing gas, and the humidity in the processing chamber 210 to change respectively from initial values P11, T11, H11 to target values P12, T12, H12 and become stable. Even in this case, the mass monitor 64 can start monitoring the mass of the substrate WF accurately quickly after the etching process for the substrate WF starts, as shown in FIG. 7D. For example, the mass monitor 64 can monitor the mass of the substrate WF gradually decreasing from an initial value M11 after timing t11. FIGS. 7A to 7D are graphs showing the operation of the substrate processing apparatus 200.

The controller 70 shown in FIG. 6 controls the operation of the substrate processing unit 220. Further, the controller 70 can perform control based on the monitoring result of the monitoring unit 60.

For example, the end point detecting unit 71 has the substrate processing unit 220 finish processing the substrate WF based on the monitoring result of the monitoring unit 60. For example, during the etching process, at timing t12 when the mass being monitored by the monitoring unit 60 reaches a target value M12 as shown in FIG. 7D, the end point detecting unit 71 determines that the amount of etching for the substrate WF has reached a target amount of etching and has the substrate processing unit 220 finish processing the substrate WF.

The anomaly detecting unit 72 detects an anomaly in the substrate processing unit 220 based on the monitoring result of the monitoring unit 60. When detecting an anomaly in the substrate processing unit 220, the anomaly detecting unit 72 has the substrate processing unit 220 suspend processing the substrate WF. For example, the anomaly detecting unit 72 obtains the temporal rate of change (rate of decrease) in the monitored value M of the monitoring unit 60 in real time during the etching process. If the temporal rate of change (rate of decrease) in the monitored value M of the monitoring unit 60 is out of a threshold range, the anomaly detecting unit 72 determines that an anomaly has occurred in the substrate processing unit 220 and has the substrate processing unit 220 suspend processing the substrate WF. Or, for example, if the monitored value M of the monitoring unit 60 is out of a threshold range as indicated by dot-dashed lines in FIG. 7D during the etching process, the anomaly detecting unit 72 determines that an anomaly has occurred in the substrate processing unit 220 and has the substrate processing unit 220 suspend processing the substrate WF.

Here, consider the case where the substrate processing apparatus 200 monitors the thickness of a film being processed by an optical method such as an ellipsometry method. In this case, it is difficult to measure the thickness of the film being processed because of the influence of the plasma PL, and thus it is difficult to detect the end point of the etching process.

In contrast, in the second embodiment, the monitoring unit 60 can highly accurately monitor the mass of the substrate WF with correcting in real time in parallel with the processing of the substrate WF by the substrate processing unit 220. Thus, even with the plasma PL being generated in the processing chamber 210, the detection of the end point of the etching process can be highly accurately performed.

It should be noted that, although the second embodiment illustrates the case where the substrate processing apparatus 200 is an ICP-type (Inductive Coupling Plasma-type) RIE apparatus, it may be a parallel-plate-type RIE apparatus, or an ECR-type (Electron Cyclotron Resonance-type) RIE apparatus, or an RIE apparatus of the type that generates a plurality of plasma therein, or the like.

### Third Embodiment

Next, a substrate processing apparatus 300 according to the third embodiment will be described. Description will be made below focusing on the differences from the first embodiment.

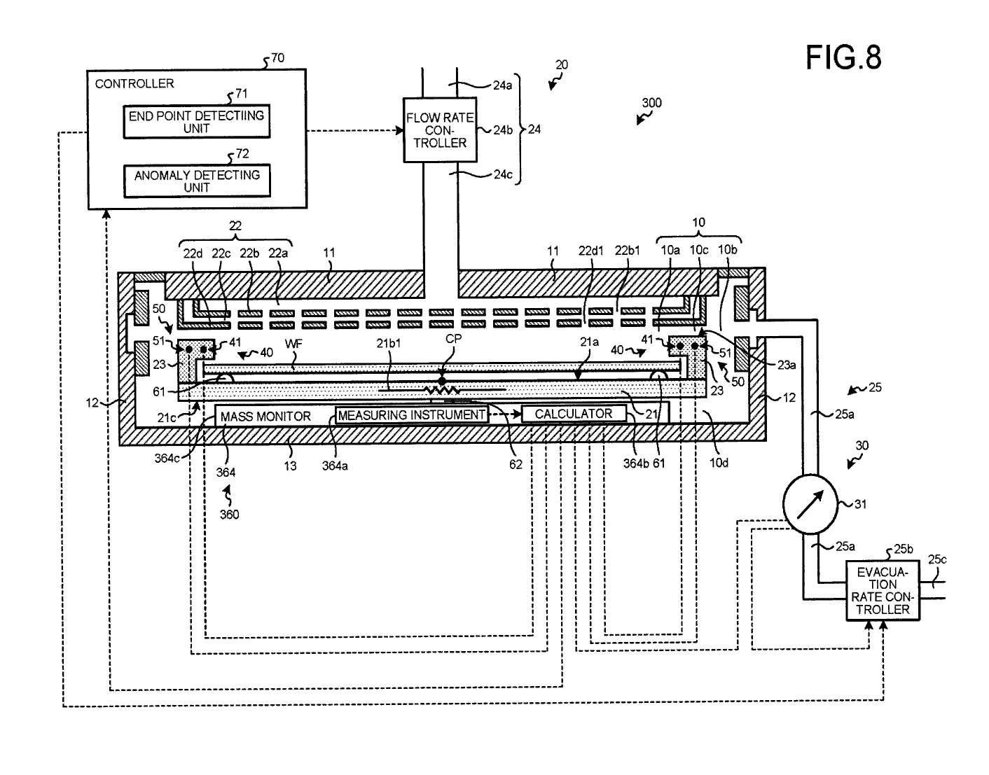

In the third embodiment, tactics for eliminating the need for the vacuum sealing structure are implemented. The substrate processing apparatus 300 comprises a monitoring unit 360 instead of the monitoring unit 60 (see FIG. 1) as shown in FIG. 8. The monitoring unit 360 does not have the vacuum sealing structure 63 (see FIG. 1) but has a mass monitor 364 instead of the mass monitor 64 (see FIG. 1). In the mass monitor 364, a measuring instrument 364a and a calculator 364b are each formed to be of a thin type. Thus, the casing 364c for housing the measuring instrument 364a and calculator 364b can also be formed to be of a thin type, and hence the mass monitor 364 can be easily housed in the space 10d between the stage 21 and the lower wall 13. Therefore, the vacuum sealing structure 63 (see FIG. 1) is unnecessary, and in addition the axial length of the shaft 62 can be shortened. Also, the hole in the lower wall 13 through which the shaft 62 would extend is unnecessary.

As such, according to the third embodiment, because the need for the vacuum sealing structure 63 (see FIG. 1) can be eliminated, the configuration of the substrate processing apparatus 300 can be simplified overall. Because the mass monitor 364 can be housed in the processing chamber 10, the configuration of the substrate processing apparatus 300 can be made compact overall.

### Fourth Embodiment

Next, a substrate processing apparatus 400 according to the fourth embodiment will be described. Description will be made below focusing on the differences from the first embodiment.

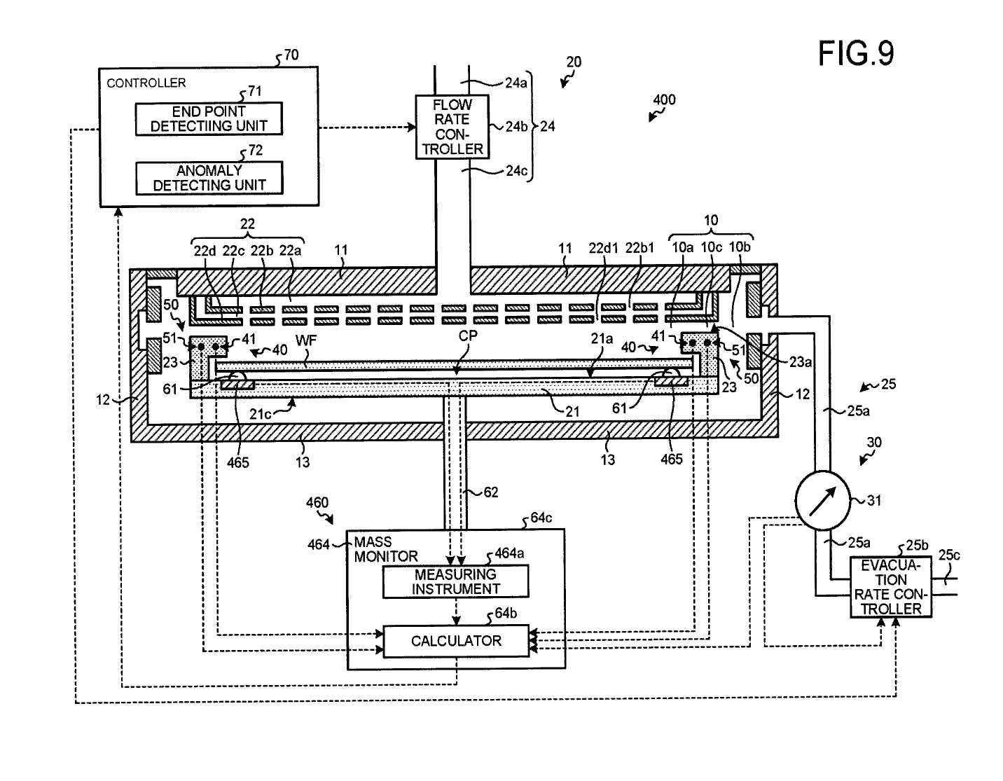

In the fourth embodiment, other tactics for eliminating the need for the vacuum sealing structure are implemented. The substrate processing apparatus 400 comprises a monitoring unit 460 instead of the monitoring unit 60 (see FIG. 1) as shown in FIG. 9. The monitoring unit 460 does not have the vacuum sealing structure 63 (see FIG. 1) but further has a plurality of piezoelectric sensors 465 and has a mass monitor 464 instead of the mass monitor 64 (see FIG. 1). The plurality of piezoelectric sensors 465 may be embedded in, e.g., the stage 21. The plurality of piezoelectric sensors 465 are provided corresponding to the plurality of substrate support members 61. Each piezoelectric sensor 465 converts the magnitude of a force received by the corresponding substrate support member 61 from the substrate WF into an electrical signal to supply to the mass monitor 464. A measuring instrument 464a of the mass monitor 464 adds up the magnitudes of forces agreeing with the electrical signals received from the piezoelectric sensors 465, thereby measuring the mass of the substrate WF according to forces acting on the substrate support members 61. That is, because the mass of the substrate WF according to forces acting on the substrate support members 61 is electrically transmitted from the substrate support members 61 to the measuring instrument 464a, the vacuum sealing structure 63 (see FIG. 1) is unnecessary.

As such, according to the fourth embodiment, because the need for the vacuum sealing structure 63 (see FIG. 1) can be eliminated, the configuration of the substrate processing apparatus 400 can be simplified overall.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing apparatus comprising:
a processing chamber in which a stage is placed, a substrate being able to be put on the stage;
a substrate processing unit configured to process the substrate inside the processing chamber; and
a monitoring unit configured to monitor a mass of the substrate via the stage with performing a correction according to a pressure, in a period when the substrate is being processed by the substrate processing unit.

2. The substrate processing apparatus according to claim 1, further comprising a pressure detecting unit configured to detect the pressure in the processing chamber, and
wherein the monitoring unit monitors the mass of the substrate via the stage, with performing the correction according to the detected pressure, in the period when the substrate is being processed by the substrate processing unit.

3. The substrate processing apparatus according to claim 2, wherein
the monitoring unit has:
a substrate support member provided on the stage;
a measuring instrument that measures the mass of the substrate agreeing with a force acting on the substrate support member from the substrate; and
a calculator that obtains a correction amount agreeing with the detected pressure and corrects the measured mass of the substrate by the correction amount to obtain a monitored value of the mass of the substrate.

4. The substrate processing apparatus according to claim 3, wherein
the monitoring unit has a plurality of the substrate support members; and
wherein the measuring instrument measures the mass of the substrate agreeing with the total of forces acting on the plurality of substrate support members.

5. The substrate processing apparatus according to claim 4, wherein
letting N be an integer of three or greater, the plurality of substrate support members include N number of substrate support members, and
wherein the N number of substrate support members are provided in positions N-fold symmetrical with respect to a center of a surface of the stage when seen in a direction perpendicular to the surface of the stage.

6. The substrate processing apparatus according to claim 3, wherein
the measuring instrument is placed outside the processing chamber, and
wherein the monitoring unit further has:
a shaft that moves up and down following up-and-down movement of the stage and transmits a force received by the stage from the substrate support member to the measuring instrument; and
a vacuum sealing structure that vacuum-seals the processing chamber while the shaft moves up and down.

7. The substrate processing apparatus according to claim 3, wherein
the measuring instrument is placed inside the processing chamber, and
wherein the monitoring unit further has:
a shaft that moves up and down following up-and-down movement of the stage in the processing chamber and transmits a force received by the stage from the substrate support member to the measuring instrument.

8. The substrate processing apparatus according to claim 3, wherein
the monitoring unit further has:
a piezoelectric sensor that converts a magnitude of a force received by the substrate support member from the substrate into an electrical signal to supply to the measuring instrument.

9. The substrate processing apparatus according to claim 1, further comprising:
a pressure detecting unit configured to detect the pressure in the processing chamber; and
a temperature detecting unit that detects a temperature of a processing gas, and
wherein the monitoring unit monitors the mass of the substrate via the stage with performing the correction according to the detected pressure and the detected temperature, in the period when the substrate is being processed by the substrate processing unit.

10. The substrate processing apparatus according to claim 9, further comprising a humidity detecting unit that detects humidity in the processing chamber, and
wherein the monitoring unit monitors the mass of the substrate via the stage with performing the correction according to the detected pressure, the detected temperature, and the detected humidity, in the period when the substrate is being processed by the substrate processing unit.

11. The substrate processing apparatus according to claim 1, further comprising an end point detecting unit that has the substrate processing unit finish processing the substrate based on the monitoring result of the monitoring unit.

12. The substrate processing-apparatus according to claim 11, wherein the end point detecting unit has the substrate processing unit finish processing the substrate in response to the mass being monitored by the monitoring unit having reached a target value.

13. The substrate processing apparatus according to claim 1, further comprising an anomaly detecting unit that detects an anomaly in processing the substrate based on the monitoring result of the monitoring unit.

14. The substrate processing apparatus according to claim 13, wherein
the anomaly detecting unit has the substrate processing unit suspend processing the substrate if detecting an anomaly based on the monitoring result of the monitoring unit.

15. The substrate processing apparatus according to claim 14, wherein
the anomaly detecting unit obtains a temporal rate of change in a monitored value of the monitoring unit and, if the obtained rate of change is out of a threshold range, has the substrate processing unit suspend processing the substrate.

16. The substrate processing apparatus according to claim 14, wherein the anomaly detecting unit has the substrate processing unit suspend processing the substrate if a monitored value of the monitoring unit is out of a threshold range.

17. A substrate processing method for a substrate processing apparatus which has a processing chamber and a substrate processing unit, a substrate being able to be put on a stage placed in the processing chamber, and the substrate processing unit processing the substrate inside the processing chamber, the method comprising:
processing the substrate by the substrate processing unit; and
monitoring a mass of the substrate via the stage with performing a correction according to a pressure in a period of processing the substrate.

18. The substrate processing method according to claim 17, wherein
the monitoring of the mass includes:
detecting the pressure in the processing chamber;
obtaining a correction amount agreeing with the detected pressure;
measuring the mass of the substrate via the stage; and
correcting the measured mass of the substrate by the correction amount to obtain a monitored value of the mass of the substrate.

19. The substrate processing method according to claim 17, further comprising having the substrate processing unit finish processing the substrate based on the result of monitoring the mass.

20. The substrate processing method according to claim 17, further comprising detecting an anomaly in the substrate processing unit based on the result of monitoring the mass.
